(19) United States
(12) Patent Application Publication
(10) Pub. No.: US 2024/0421210 A1
(43) Pub. Date: Dec. 19, 2024

(54) HIGH-VOLTAGE METAL GATE DEVICE AND PROCESS METHOD FOR THE SAME

(71) Applicant: Shanghai Huali Integrated Circuit Corporation, Shanghai (CN)

(72) Inventors: Zhi Tian, Shanghai (CN); Haoyu Chen, Shanghai (CN); Hua Shao, Shanghai (CN)

(73) Assignee: Shanghai Huali Integrated Circuit Corporation, Shanghai (CN)

(21) Appl. No.: 18/641,881

(22) Filed: Apr. 22, 2024

(30) Foreign Application Priority Data
Jun. 13, 2023 (CN) 202310698772.6

(51) Int. Cl. H01L 29/66; H01L 29/423; H01L 29/49; H01L 29/78

(52) U.S. Cl. CPC H01L 29/66484; H01L 29/4236; H01L 29/4933; H01L 29/7831

(57) ABSTRACT

This application discloses a process method for a high-voltage metal gate device. The method includes: forming a first STI region on a substrate; etching the first STI region to form a first groove; covering the first groove with a gate oxide layer and a high-k dielectric layer; depositing a polysilicon layer to fill the first groove; depositing a silicon nitride hard mask and a silicon oxide hard mask on the polysilicon layer in the first groove to form a second groove, removing the silicon oxide hard mask; implanting a high-voltage area P-type source and drain; forming an interlayer dielectric layer to cover an auxiliary gate region including the second groove; and forming contact holes to connect to the refractory silicide through the interlayer dielectric layer.

### CROSS-REFERENCE TO RELATED APPLICATIONS

This application claims priority to Chinese patent application No. 202310698772.6,filed on Jun. 13, 2023, the disclosure of which is incorporated herein by reference in its entirety.

### TECHNICAL FIELD

This application relates to the field of semiconductor technology, and in particular, to a high-voltage metal gate device and a process method for making the same.

### BACKGROUND

Organic Light Emitting Diode (OLED), as the third-generation display technology, is a type of device with light-emitting from a current-injection composite. Its many main advantages include high brightness, high contrast, wide viewing angle, fast response speed, low operating voltage, strong adaptability, high energy conversion efficiency, and simple manufacturing process. Due to the significant technological advantages and application prospects, the OLED devices have received widespread attention from both the academic and industrial areas.

OLED is a type of current driven devices, and the current density of an OLED device depends on the driving voltage applied at two ends of the device. A higher driving voltage applying on the device increases the device current density. However, during long-term use, these OLED devices will age, such that the relationship between the driving voltage, the current density, and luminous brightness may not always remain a constant. The most direct manifestation of the OLED device aging is an increase in the OLED turn-on voltage as well as a decrease in the luminous efficiency. To maintain the same luminous brightness, it is necessary to increase the OLED flow current to achieve the current function, resulting in a higher-voltage applied to the OLED devices.

In addition, the internal storage capacity of an OLED is limited, so an external memory must be used to store OLED's image data, for example, the Static Random Access Memory (SRAM) has become a commonly used memory in OLED for its high speed of read-and-write, as well as its ability to maintain data without the refresh operation at power-on time. Thus, OLED technology has been further advanced when combining with the advanced logic technology. At the present time, one of the advanced semiconductors manufacturing technology nodes is 28 nm which applies the high-k dielectric material and metal gates (28HK MG), which has advantage of high performance and low voltage. In the 28HK MG technology, it is necessary to integrate the low-voltage SRAM with the high-voltage driving components, but a high voltage needs thick silicon gate oxide, which influences the subsequent process of the metal gate. In order to be compatible with the metal gate technology in subsequent process development, a high-voltage (HV) area will be subjected to recessing of an active area, so the thick silicon oxide can be grown to closely match the height of the active area.

A high-voltage device (HV) made with 28 nm process includes a Field Diffusion Drain structure, in which the source and the drain each includes a Shallow Trench Isolation (STI) structure. When the device is turned on, a current is transmitted through the vicinity of STI.

When a high voltage is applied to both the gate and drain ends, the STI corner below the gate is prone to capture holes from the channel during the initial operation, causing an increase in current and a decrease in on-resistance. As the working time increases, the STI corner close to the drain is prone to trap electrons, resulting in a decrease in the corresponding current and an increase in on-resistance, therefore the device becomes unstable. This effect is mainly caused by collisional ionization and vertical electric field distribution, when the current is close to the Si/SiO2 interface under the high gate and drain voltages. (Reference: On-Resistance Degradation Induced by Hot-Carrier Injection in LDMOS Transistors WithSTI in the Drift Region, published on IEEE ELECTRON DEVICE LETTERS, VOL. 29, NO. 9, September 2008, by Jone F. Chen).

### BRIEF SUMMARY

According to one embodiment of this application, a high-voltage metal gate device is provided which is reliable when the gate and drain voltages are simultaneously high.

According to one embodiment of this application, process method is provided for making a high-voltage metal gate device, the process method at least includes:
step 1: providing a substrate, a first STI region is formed on the substrate, the first STI region is surrounded by a first high-voltage area N-type diffusion region, and a second high-voltage area N-type diffusion region is formed on one side of the first high-voltage area N-type diffusion region and is spaced apart from the first high-voltage area N-type diffusion region;
step 2: etching back the first STI region to form a first groove in the first STI region, herein the first groove is formed in an auxiliary gate region, and an upper surface of the substrate between the first high-voltage area N-type diffusion region and the second high-voltage area N-type diffusion region is in a metal gate region;
step 3: depositing a gate oxide layer and a high-k dielectric layer to cover the first groove in the auxiliary gate region,, followed by depositing a polysilicon layer to fill the first groove;
step 4: sequentially depositing a silicon nitride hard mask and a silicon oxide hard mask on the polysilicon layer in the first groove to form a second groove on the polysilicon layer, forming a stack of the silicon nitride hard mask and the silicon oxide hard mask;
step 5: sequentially etching the silicon oxide hard mask, the silicon nitride hard mask and the polysilicon layer, removing the silicon oxide hard mask, the silicon nitride hard mask and the polysilicon layer outside the second groove, and reserving the polysilicon layer in the first groove;
step 6: forming the a high-voltage area P-type source and drain in the auxiliary gate region by implanting ions on two sides of the second groove to form refractory silicide on the polysilicon layer;
step 7: forming an interlayer dielectric layer to cover the auxiliary gate region and the second groove in the auxiliary gate region; and
step 8: forming contact holes passing through the interlayer dielectric layer on the refractory silicide.

According to some embodiments, in step 2, the back-etched thickness of the first STI region is about 300 Å.

According to some embodiments, the substrate is further provided with a medium-voltage device region, and the medium-voltage device region is provided with an oxide layer.

According to some embodiments, in step 2, after the first STI region is etched back, the medium-voltage device region is etched back and the oxide layer in the medium-voltage device region is removed; in the process of etching back the medium-voltage device region, the first groove in the first STI region is etched to a thickness of about 100 Å; in the process of removing the oxide layer in the medium-voltage device region, the first groove in the first STI region is etched to a thickness of 250 Å.

According to some embodiments, in step 3, while the gate oxide layer and the high-k dielectric layer fill in the first groove in the auxiliary gate region, they are disposed in the metal gate region; and while the polysilicon layer fills the first groove, it is also deposited on the high-k dielectric layer in the metal gate region.

According to some embodiments, in step 7, before the interlayer dielectric layer is formed, a photoresist disposed in the auxiliary gate region is patterned to etch back the polysilicon layer in the metal gate region.

According to some embodiments, in step 1, a second STI region and a third STI region are formed on one side of the first STI region and a fourth STI region disposed on the other side of the first STI region are further formed on the substrate; and a first high-voltage area P-type diffusion region is formed between the second STI region and the third STI region.

According to some embodiments, in step 2, the process method further includes forming a second high-voltage area N-type diffusion region on one side of the first high-voltage area N-type diffusion region away from the first high-voltage area P-type diffusion region; a second high-voltage area P-type diffusion region is provided between the second high-voltage area N-type diffusion region and the fourth STI region.

According to some embodiments, in step 1, the substrate is further provided with a high-voltage P-type potential well that surrounds the first high-voltage area P-type diffusion region, the first high-voltage area N-type diffusion region, the second high-voltage area N-type diffusion region, and the second high-voltage area P-type diffusion region.

According to some embodiments, step 6 further includes: respectively doping source and drain region P-type in the first high-voltage area P-type diffusion region and the second high-voltage area P-type diffusion region; and respectively performing N-type doping in the source and drain regions in the first high-voltage area N-type diffusion region and the second high-voltage area N-type diffusion region.

This embodiment of the application further provides a high-voltage metal gate device, the device at least includes:
a substrate and a high-voltage P-type potential well on the substrate, wherein the high-voltage P-type potential well is formed with a first high-voltage area N-type diffusion region; a second high-voltage area N-type diffusion region, a first high-voltage area P-type diffusion region, and a second high-voltage area P-type diffusion region surrounded by the high-voltage P-type potential well;
wherein the first high-voltage area N-type diffusion region is provided with a first STI region which is surrounded by the first high-voltage area N-type diffusion region; wherein one side of the first STI region is provided with a second STI region and a third STI region; the other side of the first STI region is provided with a fourth STI region; the first high-voltage area P-type diffusion region is arranged to be between the second STI region and the third STI region; the second high-voltage area N-type diffusion region is arranged to be on one side of the first high-voltage area N-type diffusion region away from the first high-voltage area P-type diffusion region; and a second high-voltage area P-type diffusion region is arranged to be between the second high-voltage area N-type diffusion region and the fourth STI region;
herein a region between the first high-voltage area N-type diffusion region and the second high-voltage area N-type diffusion region on the substrate is formed with a gate oxide layer, a high-k dielectric layer which is disposed on the gate oxide layer and a metal gate which is disposed on the high-k dielectric layer, and herein the sides of the metal gate have sidewalls;
here the first STI region includes a first groove, a region where the first groove is formed is an auxiliary gate region, a gate oxide layer is disposed on the first groove and a high-k dielectric layer is disposed on the gate oxide layer; a polysilicon layer fills into the first groove; a second groove is disposed on the polysilicon layer and the second groove includes a stack of a silicon nitride hard mask and a silicon oxide hard mask; a refractory silicide layer is disposed on the polysilicon layer and spread on two sides of the second groove; an interlayer dielectric layer is disposed on the auxiliary gate region and the second groove in the auxiliary gate region; and contact holes are arranged to pass through the interlayer dielectric layer and connect on the refractory silicide. As described above, the high-voltage metal gate device and its process method disclosed in this application have the following beneficial effects: this technique opens the etching region of the high-voltage active area and the medium-voltage etching region in the shallow trench isolation region of the original high-voltage device to form a polysilicon gate therein, and leads out the polysilicon gate in the region through the refractory silicide, thus achieving a voltage-controllable high-voltage channel. By adjusting the voltage of the auxiliary gate, the on current can be kept away from the interface between silicon oxide and silicon during the operation of the high-voltage device, thus improving the problem related to the reliability caused by high current in the high-voltage device and improving the problem of instability of the device during initial and long-term operation.

### BRIEF DESCRIPTION OF THE DRAWINGS

FIG. 1 to FIG. 8 illustrate schematic diagrams of structures at each stage of the process method for a high-voltage metal gate device according to an embodiment of this application.

FIG. 9 illustrates a schematic diagram of the structure of a high-voltage metal gate device according to an embodiment of this application.

### DETAILED DESCRIPTION OF THE EMBODIMENTS

The embodiments of this application will be described below through specific examples. Those skilled in the art can easily understand the other advantages and effects of this application from the content disclosed in this description. This application may also be implemented or applied through other different specific implementation modes, and the details in this description may be modified or changed based on different perspectives and applications without deviating from the spirit of this application.

Please refer to FIG. 1 to FIG. 9. It is to be understood that the drawings provided in the embodiments are only used for schematically describing the basic concept of this application. Therefore, the drawings only show the components related to this application and are not drawn according to the actual number, shape, and size of the components during implementation. The type, number and scale of each component during actual implementation may be freely changed, and the layout of the component may also be more complex.

This application provides a process method for a high-voltage metal gate device. Referring to FIG. 1 to FIG. 9, the process method at least includes the following steps:

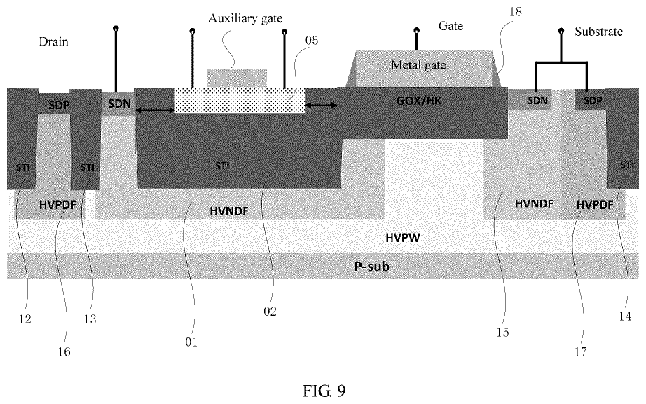

In step 1, a substrate is provided. A first STI region is formed on the substrate. The first STI region is surrounded by a first high-voltage area N-type diffusion region. A second high-voltage area N-type diffusion region is formed on one side of the first high-voltage area N-type diffusion region and is spaced apart from the first high-voltage area N-type diffusion region. Referring to FIG. 9, the substrate (p-sub) is a P-type substrate, which is formed with a first STI region 02. The first STI region 02 is surrounded by a first high-voltage area N-type diffusion region 01. The second high-voltage area N-type diffusion region 15 is formed on one side of the first high-voltage area N-type diffusion region 01 and is spaced apart from the first high-voltage area N-type diffusion region 01.

Further, according to this embodiment of this application, in step 1, the substrate is further provided with a medium-voltage device in a medium-voltage device region, and the medium-voltage device region includes an oxide layer (FIG. 9 does not show the medium-voltage device region). In this embodiment, in step 1, a second STI region 12 and a third STI region 13 formed on one side of the first STI region 02 and a fourth STI region 14 formed on the other side of the first STI region 02 are further formed on the substrate (p-sub); a first high-voltage area P-type diffusion region 16 is formed between the second STI region 12 and the third STI region 13.

Further, in this embodiment of this application, in step 1, the substrate (p-sub) is further provided with a high-voltage P-type potential well (HVPW) that surrounds the first high-voltage area P-type diffusion region 16, the first high-voltage area N-type diffusion region 01, the second high-voltage area N-type diffusion region 15, and the second high-voltage area P-type diffusion region 17.

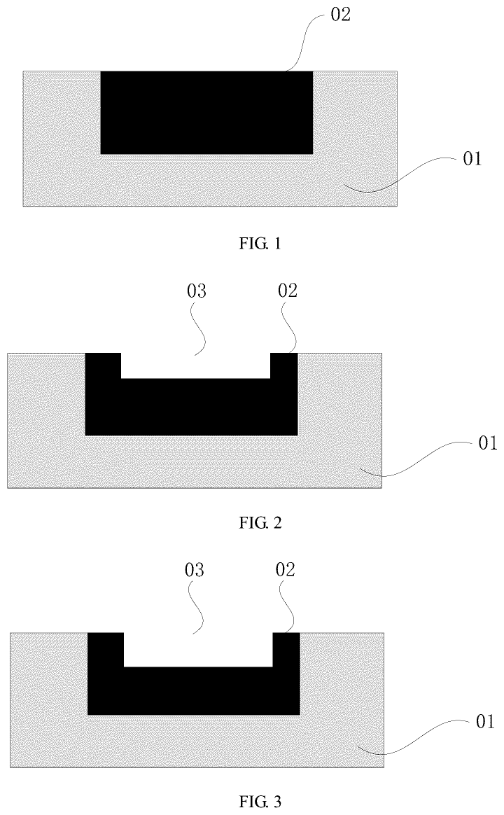

Referring to FIG. 1, the first STI region 02 is surrounded by the first high-voltage area N-type diffusion region 01. The first STI region 02 in FIG. 1 has not been etched back, while the first STI region 02 in FIG. 2 and FIG. 9 has been etched back.

Referring to FIG. 2, in step 2, the first STI region 02 is etched back to form a first groove 03 in the first STI region 02. A region where the first groove 03 is formed is in an auxiliary gate region. The auxiliary gate will be formed in the auxiliary gate region shown in FIG. 9. In FIG. 9, a metal gate will be formed in a metal gate region which is arranged to be on the upper surface of the substrate and between the right end of the first high-voltage area N-type diffusion region 01 and the left end of the second high-voltage area N-type diffusion region 15 (i.e., the metal gate region is at the upper surface between the first high-voltage area N-type diffusion region 01 and the second high-voltage area N-type diffusion region 15).

Further, according to the embodiment, referring to FIG. 2, in step 2, the first STI region 02 is etched first time and the back-etched thickness is about 300 Å. Referring to FIG. 3, further, according to this embodiment, in step 2, after the first STI region 02 in FIG. 2 is etched the first time, the first STI region 02 is etched back the second time preparing for the medium-voltage device region (not shown),and then remove the oxide layer (not shown) in the medium-voltage device region; in the process of etching back the medium-voltage device region, the first groove 03 in the first STI region 02 in FIG. 2 is etched, and the etched-off thickness is about 100 Å; in the process of removing the oxide layer (not shown) in the medium-voltage device region, the first groove 03 in the first STI region 02 is further etched again for the third time, and the etched-off thickness is 250 Å. After the three etchings, a final groove structure in FIG. 3 is formed. Accordingly, after three etchings, the final depth of the first groove 03 in FIG. 3 has become about 650 Å.

Referring to FIG. 9, further, according to this embodiment of this application, in step 2, the second high-voltage area N-type diffusion region 15 is formed on another side of the first high-voltage area N-type diffusion region 01 away from the first high-voltage area P-type diffusion region 16; and a second high-voltage area P-type diffusion region 17 is formed between the second high-voltage area N-type diffusion region 15 and the fourth STI region 14.

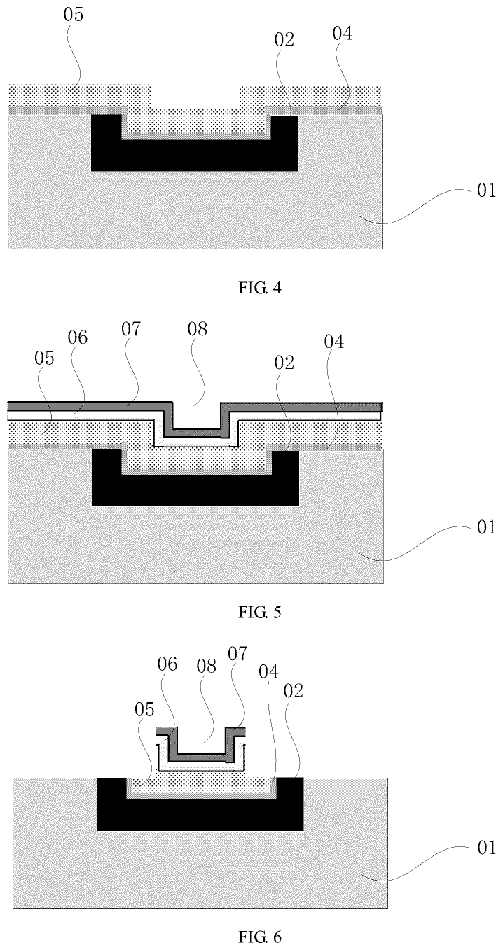

Referring to FIG. 4, in step 3, disposing a stack 04 comprising a gate oxide layer and a high-k dielectric layer on a top surface of the first groove 03 in the auxiliary gate region, and depositing a polysilicon layer 05 to fill the first groove 03.

Further, according to this embodiment, in step 3, while the first groove 03 in the auxiliary gate region is covered with the stack 04 of the gate oxide layer and the high-k dielectric layer, the stack 04 of the gate oxide layer and the high-k dielectric layer is also formed in the metal gate region; while the polysilicon layer 05 is deposited to fill the first groove 03, the polysilicon layer 05 is also deposited on the stack of the gate oxide layer and the high-k dielectric layer in the metal gate region.

Referring to FIG. 5, in step 4, a silicon nitride hard mask 06 is deposited on the polysilicon layer 05 in the first groove 03 and a silicon oxide hard mask 07 is then deposited on the silicon nitride hard mask 06. As a result, a second groove 08 is formed in the stack of the silicon nitride hard mask 06 and the silicon oxide hard mask 07 on the polysilicon layer 05.

Referring to FIG. 6, in step 5, the silicon oxide hard mask 07, the silicon nitride hard mask 06 and the polysilicon layer 05 are top down etched via patterning on the second groove 08, the silicon oxide hard mask 07, the silicon nitride hard mask 06 and the polysilicon layer 05 outside the second groove 08 are removed through patterning, and the polysilicon layer 05 in the first groove 03 is reserved.

Referring to FIG. 7, in step 6, a high-voltage area P-type source and drain are implanted in the auxiliary gate region on both sides of the second groove 08 to form a refractory silicide layer 09 on the polysilicon layer 05.

Referring to FIG. 9, further, according to this embodiment, step 6 further includes: respectively forming source and drain region P-type doping (SDP) in the first high-voltage area P-type diffusion region 16 and the second high-voltage area P-type diffusion region 17; and respectively forming source and drain region N-type doping (SDN) in the first high-voltage area N-type diffusion region 01 and the second high-voltage area N-type diffusion region 15.

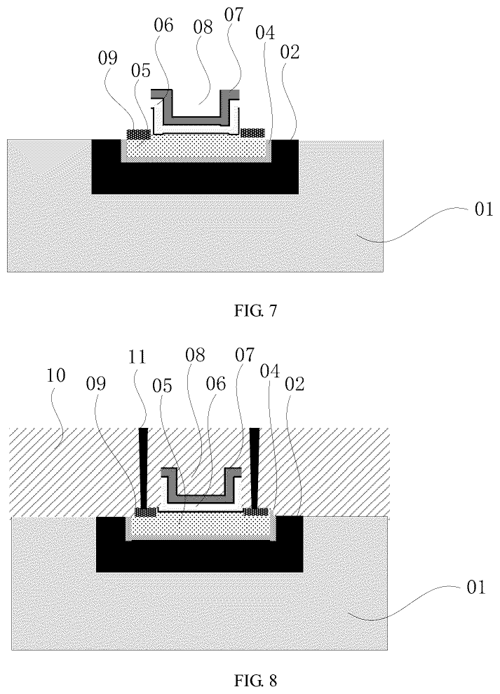

Referring to FIG. 8, in step 7, an interlayer dielectric layer 10 is formed to cover the auxiliary gate region and the second groove 08 in the auxiliary gate region.

Further, in this embodiment of this application, in step 7, before the interlayer dielectric layer is formed, the auxiliary gate region is covered with a photoresist to etch back the polysilicon layer in the metal gate region.

Referring to FIG. 8, in step 8, contact holes 11 passing through the interlayer dielectric layer 10 are formed to connect to the refractory silicide layer 09.

Referring to FIG. 9, this embodiment further discloses a high-voltage metal gate device, at least including:
a p-type substrate (p-sub) and a high-voltage P-type potential well (HVPW) disposed on the substrate (p-sub). The high-voltage P-type potential well (HVPW) includes a first high-voltage area N-type diffusion region 01, a second high-voltage area N-type diffusion region 15, a first high-voltage area P-type diffusion region 16 and a second high-voltage area P-type diffusion region 17, all of which are formed in the high-voltage P-type potential well (HVPW).

A first STI region 02 is arranged to be surrounded by the first high-voltage area N-type diffusion region 01. A second STI region 12 and a third STI region 13 are arranged to be at one side of the first STI region 02. A fourth STI region 14 is arranged to be at the other side of the first STI region 02. The first high-voltage area P-type diffusion region 16 is arranged to be between the second STI region 12 and the third STI region 13. The second high-voltage area N-type diffusion region 15 is arranged to be on another side of the first high-voltage area N-type diffusion region 01 away from the first high-voltage area P-type diffusion region 16. A second high-voltage area P-type diffusion region 17 is arranged between the second high-voltage area N-type diffusion region 15 and the fourth STI region 14.

A metal gate structure is arranged between the first high-voltage area N-type diffusion region 01 and the second high-voltage area N-type diffusion region 15 over the substrate. The metal gate structure includes a gate oxide layer (GOX), a high-k dielectric layer (HK) disposed on the gate oxide layer (GOX), and a metal gate formed on the high-k dielectric layer (HK). The metal gate structure also includes sidewalls 18.

The auxiliary gate in FIG. 9 is a simplified illustration of the second groove 08 (i.e., the structure formed in step 4) shown in FIG. 8. The second groove 08 is formed by patterning a stack of the silicon nitride hard mask 06 and the silicon oxide hard mask 07 shown in FIG. 6. The first STI region is formed with a first groove 02, wherein an auxiliary gate region is formed in the first groove, the first groove 03 is covered with a stack of a gate oxide layer and a high-k dielectric layer formed on the gate oxide layer (not shown in FIG. 9). A polysilicon layer 05 fills in the first groove 03; a second groove 08 is formed by patterning the stack of the silicon nitride hard mask 06 and the silicon oxide hard mask 07, and the polysilicon layer 05 and formed by (as shown in FIG. 5). A refractory silicide layer is formed on the polysilicon layer 05 at both sides of the second groove. An interlayer dielectric layer 10 is deposited on the auxiliary gate region and in the second groove 08 in the auxiliary gate region. Contact holes are formed through the interlayer dielectric layer and connecting to the refractory silicide layer.

To sum up, this application opens the etching region of the high-voltage active area and the medium-voltage etching region in the shallow trench isolation region of the original high-voltage device to form a polysilicon gate therein, and leads out the polysilicon gate in the region through the refractory silicide, thus achieving a voltage-controllable high-voltage channel. By adjusting the voltage of the auxiliary gate, the on current can be kept away from the interface between silicon oxide and silicon during the operation of the high-voltage device, thus improving the problem related to the reliability caused by high current in the high-voltage device and improving the problem of instability of the device during initial and long-term operation. Therefore, this application overcomes various drawbacks in the existing technology and has a great industrial utilization value.

The above embodiments are only intended to exemplarily describe the principle and efficacy of this application, instead of limiting this application. Anyone familiar with this technology may modify or change the above embodiments without departing from the spirit and scope of this application. Therefore, all equivalent modifications or changes made by those with ordinary knowledge in the technical field without departing from the spirit and technical concept disclosed in this application should still be covered by the claims of this application.

What is claimed is:

1. A process method for a high-voltage metal gate device, wherein the process method comprises:
step 1: providing a substrate, forming a first high-voltage area N-type diffusion region on the substrate, forming a first shallow trench isolation (STI) region in the first high-voltage area N-type diffusion region, and forming a second high-voltage area N-type diffusion region at one side of the first high-voltage area N-type diffusion region on the substrate, wherein the second high-voltage area N-type diffusion region is spaced apart from the first high-voltage area N-type diffusion region;
step 2: etching back the first STI region to form a first groove in the first STI region, forming an auxiliary gate region in the first groove, and forming a metal gate region between the first high-voltage area N-type diffusion region and the second high-voltage area N-type diffusion region;
step 3: forming a gate oxide layer on a top surface of the first groove in the auxiliary gate region, forming a high-k dielectric layer one the gate oxide layer and depositing a polysilicon layer on the high-k dielectric layer, wherein the polysilicon layer fills the first groove;
step 4: sequentially depositing a silicon nitride hard mask and a silicon oxide hard mask on the polysilicon layer to form a second groove in a stack of the polysilicon layer, the silicon nitride hard mask and the silicon oxide hard mask;
step 5: sequentially etching the silicon oxide hard mask, the silicon nitride hard mask and the polysilicon layer, removing the silicon oxide hard mask, the silicon nitride hard mask, and the polysilicon layer outside the second groove through a patterning process, wherein a part of the polysilicon layer is reserved in the first groove;
step 6: forming, by ion implantation, a high-voltage area P-type source and a high-voltage area P-type drain in the auxiliary gate region at two sides of the second groove respectively, and forming a refractory silicide layer on the reserved polysilicon layer in the first groove;
step 7: forming an interlayer dielectric layer to cover the auxiliary gate region including the second groove; and
step 8: forming contact holes connecting to the refractory silicide through the interlayer dielectric layer.

2. The process method for the high-voltage metal gate device according to claim 1, wherein in step 2, an etched thickness in the first STI region is about 300 Å.

3. The process method for the high-voltage metal gate device according to claim 1, wherein step 1 further comprises forming a medium-voltage device region in the substrate, wherein the medium-voltage device region comprises an oxide layer.

4. The process method for the high-voltage metal gate device according to claim 3, wherein step 2 further comprises: after etching the first STI region, etching the medium-voltage device region and removing the oxide layer in the medium-voltage device region, wherein during the etching of the medium-voltage device region, the first groove in the first STI region is etched with an etched-off thickness at about 100 Å, wherein during removing the oxide layer in the medium-voltage device region, the first groove in the first STI region is etched with an etched-off thickness at about 250Å.

5. The process method for the high-voltage metal gate device according to claim 1, wherein step 3 further comprises: while forming the gate oxide layer and the high-k dielectric layer in the first groove in the auxiliary gate region, a gate oxide layer and a high-k dielectric layer are also formed in the metal gate region; and while depositing the polysilicon layer to fill the first groove, a polysilicon layer is also deposited on the high-k dielectric layer in the metal gate region.

6. The process method for the high-voltage metal gate device according to claim 5, wherein step 7 further comprises, before forming the interlayer dielectric layer, depositing a photoresist in the auxiliary gate region and performing a patterning process in the polysilicon layer in the metal gate region.

7. The process method for the high-voltage metal gate device according to claim 1, wherein step 1 further comprises: forming a second STI region and a third STI region on one side of the first STI region, forming a fourth STI region on the other side of the first STI region, and forming a first high-voltage area P-type diffusion region between the second STI region and the third STI region.

8. The process method for the high-voltage metal gate device according to claim 7, wherein step 2 further comprises: forming the second high-voltage area N-type diffusion region on one side of the first high-voltage area N-type diffusion region away from the first high-voltage area P-type diffusion region; and forming a second high-voltage area P-type diffusion region between the second high-voltage area N-type diffusion region and the fourth STI region.

9. The process method for the high-voltage metal gate device according to claim 8, wherein step 1 further comprises: forming a high-voltage P-type potential well that surrounds the first high-voltage area P-type diffusion region, the first high-voltage area N-type diffusion region, the second high-voltage area N-type diffusion region, and the second high-voltage area P-type diffusion region in the substrate.

10. The process method for the high-voltage metal gate device according to claim 8, wherein step 6 further comprises: respectively performing source and drain region P-type doping in the first high-voltage area P-type diffusion region and the second high-voltage area P-type diffusion region; and respectively performing source and drain region N-type doping in the first high-voltage area N-type diffusion region and the second high-voltage area N-type diffusion region.

11. A high-voltage metal gate device, at least comprising:
a substrate and a high-voltage P-type potential well on the substrate, the high-voltage P-type potential well, wherein the high-voltage P-type potential well is arranged to surround a first high-voltage area N-type diffusion region, a second high-voltage area N-type diffusion region, a first high-voltage area P-type diffusion region and a second high-voltage area P-type diffusion region by the high-voltage P-type potential well;
a first shallow trench isolation (STI) region, surrounded by the first high-voltage area N-type diffusion region;
a second STI region and a third STI region arranged at one side of the first STI region;
a fourth STI region arranged at the other side of the first STI region, wherein the first high-voltage area P-type diffusion region is arranged between the second STI region and the third STI region, wherein the second high-voltage area N-type diffusion region is arranged at another side of the first high-voltage area N-type diffusion region away from the first high-voltage area P-type diffusion region;
a second high-voltage area P-type diffusion region arranged between the second high-voltage area N-type diffusion region and the fourth STI region;
a metal gate structure arranged between the first high-voltage area N-type diffusion region and the second high-voltage area N-type diffusion region on the substrate, wherein the metal gate structure comprises a gate oxide layer, a high-k dielectric layer on the gate oxide layer and a metal gate on the high-k dielectric layer, wherein the metal gate comprises a sidewall;
a first groove arranged in the first STI region;
an auxiliary gate region arranged in the first groove;
a gate oxide layer disposed on the first groove, and a high-k dielectric layer disposed on the gate oxide layer;
a polysilicon layer disposed on the high-k dielectric layer;
a silicon nitride hard mask and a silicon oxide hard mask disposed on the polysilicon layer;
a second groove arranged on a stack which includes the polysilicon layer, the silicon nitride hard mask and the silicon oxide hard mask;
a refractory silicide layer disposed on the polysilicon layer on two sides of the second groove;
an interlayer dielectric layer disposed on the auxiliary gate region and the second groove in the auxiliary gate region; and
contact holes arranged through the interlayer dielectric layer and connecting to the refractory silicide layer.
